(19) United States
(12) Patent Application Publication
(10) Pub. No.: US 2006/0202673 A1
(43) Pub. Date: Sep. 14, 2006

(54) Method and system for feeding electrical energy into an alternating current electrical mains

(76) Inventors: Antonius Hendrikus Franciscus Elisabeth Doedee, Eindhoven (NL); Machiel Antonius Martinus Hendrix, Eindhoven (NL); Janmarinus Cornelius Adrianus Putmans, Gemonde (NL)

Correspondence Address: PHILIPS INTELLECTUAL PROPERTY & STANDARDS, P.O. BOX 3001, BRIARCLIFF MANOR, NY, 10510, US

(21) Appl. No.: 10/539,357

(22) PCT Filed: Nov. 24, 2003
(86) PCT No.: PCT/IB03/05483

§ 371 Date: Jun. 15, 2005

(30) Foreign Application Priority Data
Dec. 19, 2002 (EP) 02080406.8

(51) Int. Cl. G01R 19/18

(52) U.S. Cl. 324/120

(57) ABSTRACT

In a method and system for feeding electrical energy into an alternating current electrical mains the mains signal is recorded and a reference signal generated. From the mains signal and the reference signal a delayed mains signal and a delayed reference signal is derived. Then, the mains signal is multiplied by the delayed reference signal and the delayed mains signal is multiplied with the reference signal. By determining a difference between the multiplied signals, a phase difference between the fundamental harmonic frequency of the mains signal and the reference signal can be derived. Making use of the phase difference, the frequency of the reference signal can be adjusted. From the reference signal a synchronization signal for synchronizing a converter is derived, the synchronization signal synchronizing an electrical output alternating current energy of the converter. Thus, energy is fed into the mains by the converter in synchronism with the fundamental harmonic frequency of the mains signal.

The invention relates to a method and system for feeding electrical energy into an alternating current electrical mains.

From EP-B-0 712 618 an adapter for converting solar energy into alternating current for supplementing a household alternating current electricity mains is known. The adapter comprises a plurality of photovoltaic solar cells which are interconnected such that a sum of output voltages exceeds an absolute value of a peak voltage of the alternating current power line. For supplying an electrical current to the mains alternating current power line, a momentary value of a line voltage is compared against a positive threshold value, such that when the momentary line voltage exceeds this threshold, electrical current flows from the adapter into the power line, while when the momentary value of the power line voltage is lower than a negative threshold value, a negative current flows from the adapter into the power line. Thus, energy is transferred into the power line when the momentary voltage value of the power line is higher than a positive threshold value and when the momentary voltage value is lower than a negative threshold value.

A problem is that the power line is subject to noise which comprises disturbances in any frequency band as well as higher harmonics of the alternating current power line signal. As a consequence, feeding energy into the mains based on the exceeding of a threshold value results in injection of energy on noise frequency bands, i.e. on higher harmonic frequency bands of the power line signal as well as on frequency bands of further noise and disturbances. Thus, higher harmonics as well as noise present on the power line tend to be amplified by the injection of energy, thus resulting in a deterioration of a quality of the power line signal.

An object of the invention is to maintain or enhance the quality of the power line signal when feeding energy into the mains.

To achieve this and other objects, the method according to the invention comprises the steps of:
a) recording a mains signal for obtaining a measured mains signal,
b) generating a reference signal having a fundamental harmonic frequency which is within a tolerance band around a fundamental harmonic frequency of the mains signal,
c) deriving a delayed mains signal from the measured mains signal,
d) deriving a delayed reference signal from the reference signal,
e) multiplying the delayed mains signal with the reference signal for obtaining a first multiplied signal,
f) multiplying the mains signal with the delayed reference signal for obtaining a second multiplied signal,
g) determining a phase difference between a fundamental harmonic frequency of the mains signal and the fundamental harmonic frequency of the reference signal by determining a difference between the first and the second multiplied signals,
h) adjusting the fundamental harmonic frequency of the reference signal based on the phase difference,
i) synchronizing a converter for converting the energy into an alternating current electrical energy, to the adjusted fundamental harmonic frequency of the reference signal, and
j) feeding the alternating current electrical energy into the mains, in phase with the reference signal. The alternating current electrical mains can be a public mains, however it is also possible that the mains is a private mains, or a private mains which is galvanically isolated from the public mains. The recording of the mains signal can take place by sampling making use of a suitable sampling frequency, however it is also possible that the mains signal is recorded in an other way, such as by analogue recording. The reference signal has a fundamental harmonic frequency within a tolerance band around the fundamental harmonic frequency of the mains signal, such that a frequency difference between the fundamental harmonic frequency of the reference signal and the fundamental harmonic frequency of the mains signal does not exceed a predetermined value. The delayed mains signal can be derived from the measured mains signal making use of any suitable delay technique, in case that the mains signal has been sampled, deriving the delayed mains signal comprises a very simple and easy to perform time shifting operation. Also, when the reference signal is generated making use of a sequence of samples, deriving the delayed reference signal comprises a simple and easy to perform time shift operation. The multiplying operation for obtaining the first and second multiplied signals comprises a multiplication in the time domain. The phase difference between the fundamental harmonic frequency of the mains signal and the reference signal can be easily determined, e.g. by calculating a difference between the first and the second multiplied signals. The phase difference determined by the method according to the invention comprises only very little disturbances by higher harmonics. To filter away such harmonics, and/or other disturbances, the method advantageously comprises the further step of, prior to step h): averaging the phase difference over a repetition time of the reference signal, which results in a further suppression of such disturbances. Alternatively, any other suitable filtering technique, such as low pass filtering, can be used. Thus, a signal (such as an analogue signal or a sampled, digital signal) is provided which provides a measure for the phase difference between the fundamental harmonic frequency component of the mains signal and the fundamental harmonic frequency component of the reference signal. Based on the phase difference, the fundamental harmonic frequency of the reference signal is adjusted, preferably such that the phase difference between the fundamental harmonic frequency components of the mains signal and the reference signal is reduced to zero or is brought to a predetermined phase difference.

Now, the converter for converting energy into the alternating current electrical energy can be synchronized to the fundamental harmonic frequency of the reference signal, and thus energy can be fed into the mains on the adjusted fundamental harmonic frequency of the reference signal which advantageously substantially equals the fundamental harmonic frequency of the mains signal. Consequently, only energy is fed into the mains on substantially the fundamental harmonic frequency of the mains signal. Thus, no, or only very little energy is fed into the mains on higher harmonics of the mains frequency or on other undesired frequency bands. Thus, the quality of the mains signal is maintained or even enhanced.

From DE 19604207 a synchronization to an alternating current voltage in a mains is known making use of a phase locked loop which is implemented in software. A disadvantage however is that a Fourier transform of the mains voltage has to be calculated which requires considerable calculation time, and thus requires considerable processing capacity to be provided by a processing means. The method according to the invention, instead of requiring calculation of a Fourier transform which comprises highly complex calculations, only requires performing a limited number of steps, each step having a low complexity. A further disadvantage of the use of a phase locked loop is that such phase locked loop incorporates a filter (such as a digital filter or an analogue filter), which introduces a delay and will reduce a synchronization speed for a synchronization to the mains signal.

Advantageously, the method comprises the further steps of: k) multiplying the mains signal with the reference signal for obtaining a third multiplied signal, l) multiplying the delayed mains signal with the delayed reference signal for obtaining a fourth multiplied signal, m) determining an amplitude of the fundamental harmonic frequency component of the mains signal by determining a sum of the third and the fourth multiplied signals, and wherein step j) comprises the further step of: j1) determining a magnitude of the electrical energy to be fed into the mains, based on the amplitude of the fundamental harmonic frequency component of the mains signal. Thus, with a limited amount of further, simple steps, a signal (such as an analogue signal or a sampled, digital signal) can be determined which provides a measure for the amplitude of the fundamental harmonic frequency component of the mains signal. The mains signal, reference signal, delayed mains signal and delayed reference signal have already been provided with steps a, b, c and d and thus the determination of the amplitude only requires performing multiplications in the time domain and determining a sum of the third and fourth multiplied signals. As the steps only comprise simple operations, they can be easily and quickly carried out. Further, use is made of the same signals which have also been provided for determining the phase difference and feeding the energy into the mains, in phase with the reference signal, and thus no further measurements are required. Consequently, the magnitude of the electrical energy to be fed into the mains, such as the magnitude of a current, can be easily determined based on a signal providing an indicator for the amplitude of the harmonic frequency component of the mains signal. The determining of the magnitude of the electrical energy to be fed into the mains can be used for providing a power control for controlling an amount of electrical power to be fed into the mains. Additionally or alternatively it is possible to provide a safety switch-off function in an easy manner, as in case of an amplitude of the fundamental harmonic frequency of the mains signal which exceeds predetermined values, feeding electrical energy into the mains can be inhibited. Also it is possible to provide an amplitude control for the mains signal, for example in case that the mains, or a part of the mains into which energy is to be fed, is disconnected from a mains generator, and thus energy is fed into the mains autonomously. The amount of electrical energy to be fed into the mains is determined based on an amplitude of the fundamental harmonic frequency component of the mains signal, and as a consequence, the determining of the magnitude of the electrical energy to be fed into the mains is accurate, as this determination is not based on any higher harmonics or noise components in the mains signal.

Advantageously, the method comprises the further step of, prior to step j1): averaging the amplitude over the repetition time of the reference signal. Thus, with a very simple filter, which hardly introduces any delay times, the small, remaining amount of higher harmonics in the signal providing a measure for the amplitude of the fundamental harmonic frequency of the mains signal can be filtered out.

Advantageously, the reference signal is a substantially sinusoidal signal which further simplifies carrying out the steps according to the method according to the invention.

Further, advantageously the delayed mains signal and the delayed reference signal are each delayed by a time period of substantially one quarter of a repetition time of the reference signal.

Advantageously, at least steps a) to j) are repeated and thus the fundamental harmonic frequency of the reference signal is repeatedly adjusted, such that any changes or fluctuations in the mains signal, and in particular in the fundamental harmonic frequency thereof, are followed. Also it is possible that the steps k) to m) and j1) are repeated, thus resulting in an adaptation of the amount of electrical energy to be fed into the mains on any fluctuation or change in the amplitude of the fundamental harmonic frequency component of the mains signal. As the steps according to the method according to the invention require no, or only little filtering (such as averaging) adjustments towards a fluctuation in a fundamental harmonic frequency of the mains signal or an amplitude of the fundamental harmonic frequency of the mains signal can be quickly carried out, as no, or only very little delay due to filtering or averaging is introduced.

The system for feeding electrical energy into an alternating current mains comprises: an energy source for supplying the electrical energy to the system, a converter for converting the electrical energy into an alternating current energy, and a synchronization circuit for synchronizing the converter to a repetition frequency of the alternating current mains, characterized in that the synchronization circuit comprises means for a) recording a mains signal for obtaining a measured mains signal,
b) generating a reference signal having a fundamental harmonic frequency which is within a tolerance band around a fundamental harmonic frequency of the mains signal, c) deriving a delayed mains signal from the measured mains signal,
d) deriving a delayed reference signal from the reference signal,
e) multiplying the delayed mains signal with the reference signal for obtaining a first multiplied signal,
f) multiplying the mains signal with the delayed reference signal for obtaining a second multiplied signal,
g) determining a phase difference between a fundamental harmonic frequency of the mains signal and the fundamental harmonic frequency the reference signal by determining a difference between the first and the second multiplied signals,
h) adjusting the fundamental harmonic frequency of the reference signal based on the phase difference,
i) synchronizing the converter to the adjusted fundamental harmonic frequency of the reference signal;
   and in that the converter comprises means for feeding the electrical energy into the mains, in phase with the reference signal.

The synchronization circuit advantageously comprises a digital signal processor, which is expected to be present in a future system for feeding electrical energy into an alternating current mains anyway. As only very simple and a limited amount of steps are to be carried out, a load provided to the digital signal processor is low, and thus a digital signal processor which is already foreseen in the system is easily able to carry out these steps, in addition to other tasks.

Advantageously, the energy source comprises at least one solar cell and the converter comprises an inverter for inverting a direct current electrical energy provided by the solar cell into an alternating current energy, in phase with the reference signal.

It will be clear to a person skilled in the art that the system according to the invention can further comprise means for carrying out the further steps according to the method according to the invention, as described above.

Further advantages and features of the method and system according to the invention will become clear from the appended drawings, in which a non-limiting embodiment of the method and system according to the invention is shown, in which:

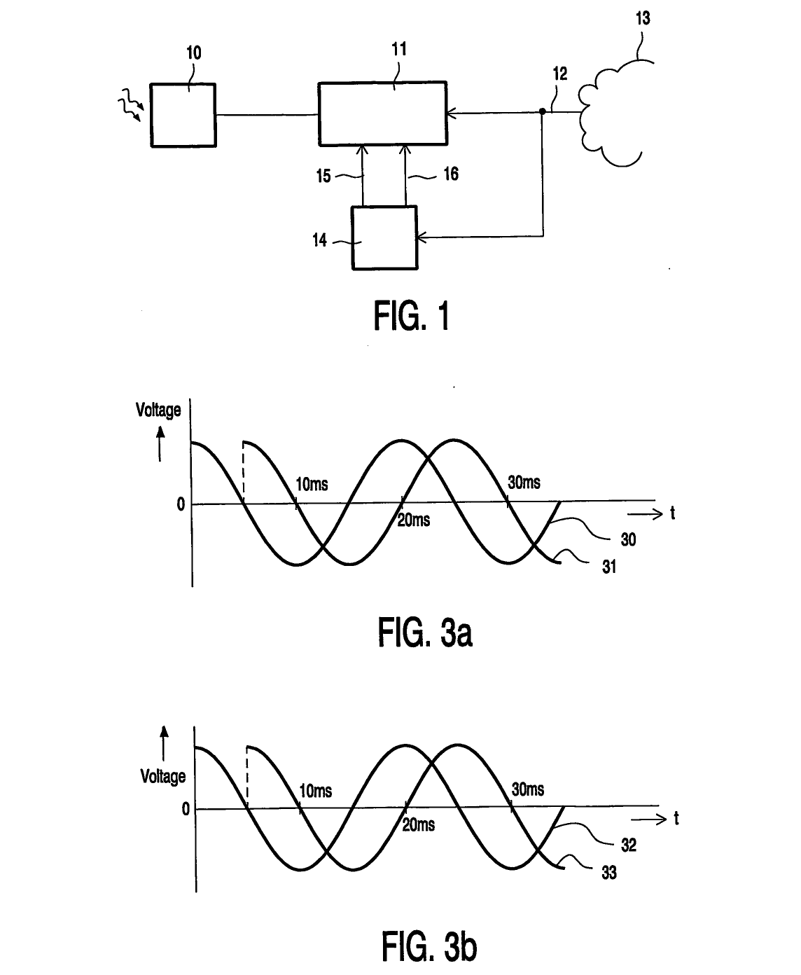

FIG. 1 shows a highly schematic block diagram of a system according to the invention;

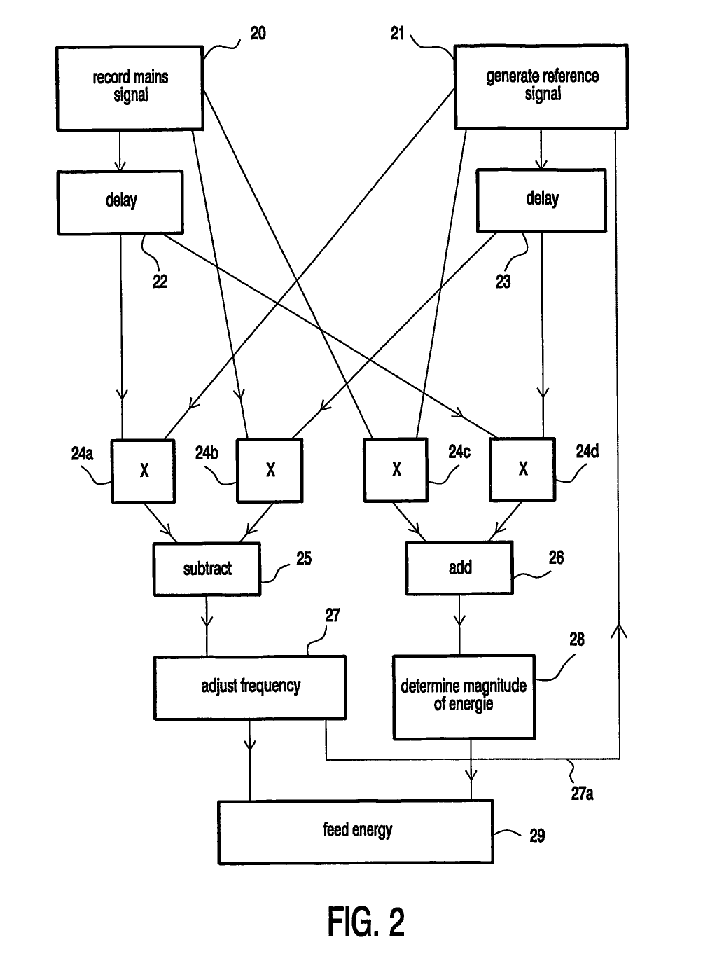

FIG. 2 shows a flow diagram of an embodiment of the method according to the invention;

FIGS. 3a and 3b show a graphical representation of a mains signal and a delayed mains signal, respectively a reference signal and a delayed reference signal;

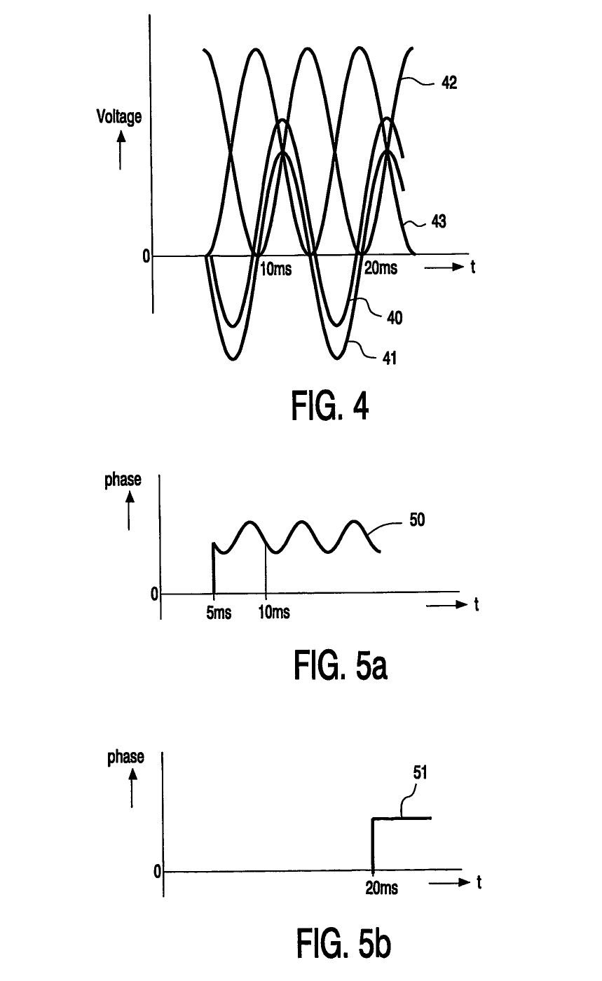

FIG. 4 shows a diagram showing first, second, third and fourth multiplied signals according to the invention;

FIGS. 5a and 5b show a diagram showing an unfiltered and an averaged signal providing a measure for the phase difference according to the invention; and

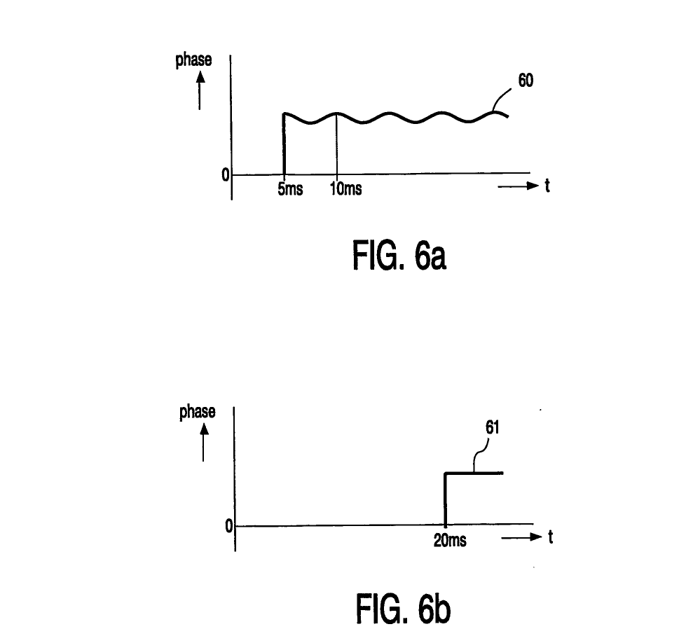

FIGS. 6a and 6b show a diagram showing an unfiltered and an averaged signal providing a measure for the amplitude of the mains signal according to the invention.

The system shown in FIG. 1 comprises a solar cell 10, an output of which is connected to an input of a converter, in this example an inverter 11. The solar cell 10 converts solar energy into electrical energy which is via the output of the solar cell 10 transferred to inverter 11. The inverter 11 converts the electrical energy into alternating current electrical energy. An output of the inverter 11 is connected to an output terminal 12 of the system, the output terminal 12 for connecting the system with a mains which has been very schematically indicated with 13. The output of the inverter, and thus the output terminal 12 is also connected to an input terminal of a synchronization circuit 14 for synchronizing the inverter to a repetition frequency of the alternating current mains 13. Therefore, the synchronization circuit 14 is provided with a synchronization output 15 which is connected to an appropriate input of the inverter 11. Although the connections between the solar cell 10, the inverter 11, the mains 13 and the synchronization circuit 14 are depicted in FIG. 1 by single lines, it will be clear to a person skilled in the art that corresponding return lines are provided, such as for example grounding connections or return lines. The synchronization circuit can for example comprise a processing unit, such as a digital signal processor which performs processing steps as will be explained below with reference to FIG. 2.

In step 20 in FIG. 2 the mains signal is recorded, which can be performed either continuously or at least during a predetermined recording time. The term mains signal refers to a signal being related to an electric quantity of the mains, preferably the mains voltage, i.e. the voltage provided by the mains. As the mains in most cases provides an alternating voltage the mains signal preferably is an alternating voltage signal. In step 21 a reference signal is generated, the reference signal being a sine signal. The frequency of the reference signal is within a tolerance band around a nominal fundamental harmonic frequency of the mains signal. As an example, if the nominal frequency of the mains signal is 50 Hz, the frequency of the reference signal will be in a tolerance band around 50 Hz, such as between 48 Hz and 52 Hz. In step 22 a delayed mains signal is derived from the measured mains signal, the mains signal in this example being delayed by a time of one quarter of a repetition period of the reference signal if the reference signal for example has a frequency of 50 Hz, the delay will be 5 ms. FIG. 3a depicts the mains signal 30 and the delayed mains signal 31. In step 23 a delayed reference signal is derived from the reference signal, the delay time advantageously being one quarter of the repetition period of the reference signal, thus also being 5 ms in case that the reference signal is 50 Hz. FIG. 3b depicts the reference signal 32 and the delayed reference signal 33.

In step 24a the delayed mains signal is multiplied in the time domain with the reference signal for obtaining a first multiplied signal while in step 24b the mains signal is multiplied in the time domain with the delayed reference signal resulting in a second multiplied signal. The first and second multiplied signals are depicted in FIG. 4 with 40 and 41 respectively. Also, in step 24c the mains signal is multiplied with the reference signal and in step 24d the delayed mains signal is multiplied with the delayed reference signal, resulting in third and fourth multiplied signals, respectively. The third and fourth multiplied signals are depicted in FIG. 4 with 42 and 43 respectively. Steps 24a, 24b, 24c and 24d can be performed in the order described, however it is also possible that these steps are performed in parallel or in any order. Also, steps 22 and 23 can be performed in parallel, or in any order.

In step 25 a difference between the first and second multiplied signals is determined, such as by subtracting the first and second multiplied signals, resulting in a difference which provides a measure for a phase difference between the fundamental harmonic frequency of the mains signal and the reference signal. The signal providing a measure for the phase difference has been depicted in FIG. 5a with 50. As shown, the signal 50 representing the phase difference comprises a ripple which consists of higher harmonics of the mains signal and/or higher harmonic frequencies of the reference signal. Although comparatively small, they can be further filtered out making use of an averaging, which results in the averaged phase signal 51 depicted in FIG. 5b. The averaging has been performed with an averaging time which is equal to the time period of the reference signal, i.e. in this example approximately 20 ms. It will be clear to a person skilled in the art that the phase signal is only available after 5 ms from start of the calculation as only after 5 ms a delayed mains signal and a delayed reference signal is available (the delay time being 5 ms). Further, the average phase signal is available again 20 ms later, as the averaging in this example is performed over a time period of 20 ms. As only a relatively low amount of higher frequency components is present in the phase signal 50, only a slight filtering, such as the averaging over one time period is required, and thus the averaged phase signal 51 is available with little delay. The third and fourth multiplied signals obtained in step 24c and 24d respectively are added in step 26 which results in a signal representing an amplitude of the fundamental harmonic frequency component of the mains signal, as depicted with 60 in FIG. 6a The signal 60 representing the amplitude of the fundamental harmonic frequency component of the mains signal is available from 5 ms on, as due to the delay operations in step 22 and 23, which in this example comprise a delay of 5 ms, the calculations can only start after 5 ms (i.e. after the delay time). As shown in FIG. 6a, the signal representing the amplitude of the fundamental harmonic frequency comprises a ripple which consists of higher harmonics of the fundamental harmonic frequency of the mains signal resp. higher harmonics of the reference signal, which can be easily filtered out, if required, advantageously by an averaging operation advantageously over a period of the reference signal, i.e. in this example approximately 20 ms. Similarly as observed above, also the averaged amplitude signal 61 is only available after a certain time period, due to the averaging, as described above with reference to the averaged phase signal 51, however as the required filtering, or averaging is only moderate, this delay time is small.

As the first and second multiplied signals 40, 41, each comprise error components which are substantially equal to each other, the difference between the first and second multiplied signals 40, 41 is substantially free of error components, which results in only a small amount of higher harmonics etc. present on the phase signal 50 and thus avoids extensive filtering. Similarly, the third and fourth multiplied signals 42 and 43 respectively have error components which are substantially similar but opposite in sign. Thus, as the difference between the third and fourth multiplied signals is determined, these error components substantially cancel each other which results in an amplitude signal 60 which is largely free of error components, such as higher harmonics. Thus, also for the amplitude signal 60, only moderate filtering is required to further reduce these error components.

In step 27, the frequency of the reference signal is adjusted (as indicated with the dotted line 27a) based on the averaged phase difference 51 as such that by the adjustment of the frequency of the reference signal the phase difference will reduce to zero or reduce to a predetermined phase difference value. Such a predetermined phase difference value can be applied to compensate for a phase difference, i.e. in case that the system is connected via a long connection (having an inductance) to the mains. In this case, a compensation can be achieved for the phase error which results from the inductance of the long connection to the mains. By bringing the phase difference between the fundamental harmonic frequency components of the mains signal and the reference signal back to zero or a predetermined value, from the reference signal a synchronization signal can now be derived which is used for synchronizing the inverter 11 via the synchronization output 15 by the synchronization circuit 14. Thus, the inverter can supply alternating current electrical energy via the output of terminal 12 to the mains 13 substantially in synchronism with the fundamental harmonic frequency of the mains signal. The synchronization circuit 14 is advantageously provided with an energy control output 16 which is connected to a corresponding input of the inverter 11, for controlling the amount of energy supplied by the inverter 11 to the mains 13. The energy control output is provided with a signal in correspondence to the filtered amplitude signal 61. As the amplitude of the fundamental harmonic frequency of the mains signal is calculated, the amount of energy to be fed into the mains can be controlled. The amount of energy to be fed into the mains 13 can for example be increased when the mains voltage is low while the amount of energy can be decreased when the mains voltage gets too high. Thus, unsafe situations can be avoided and reliable operations of electric appliances and other equipment connected to the mains can be certified.

The steps according to the method according to the invention are advantageously repeated. It will be clear that the steps can be repeated continuously, periodically or in a pipeline manner, such that a periodic or continuous adjustment of the reference frequency to the fundamental harmonic frequency of the mains signal and a continuous or periodic adjustment of the amount of energy to be fed into the mains, is achieved.

The mathematical principle applied by the method and system according to the invention will now be described. Assume that the mains signal is described by
A₁ cos(ωt+φ)+A₃ cos(3ωt+φ₃)+A₅ cos(5ωt+φ₃)+ (1)
in which Aᵢ and φᵢ are the amplitude and phase of the i-th harmonic component and ω is the mains frequency in radians per second, and that the reference signal is described by
A_{ref} cos ω_{vco}t, (2)
in which A_{ref} is the reference amplitude and ω_{vco} the reference frequency in radians per second.
The delayed mains signal is described by
A₁ cos ω((t−T/4)+A₃ cos(3ω(t−T/12)−φ₃)+A₅ cos(5107 (t−T/20)−φ₅)+ (3)
and the delayed reference signal by
A_{ref} sin ω_{vco}t. (4)
Assuming in both cases a delay time of T/4 seconds, where ωT=2π, makes ω_{vco} equal to ω. Multiplication of expressions (1) and (4) provides

$$\frac{{A}_{1} {A}_{ref}}{2} [ - sin φ + sin ( 2 ω t + φ ) ] + \frac{{A}_{3} {A}_{ref}}{2} [ - sin ( 2 ω t + {φ}_{3} ) + sin ( 4 ω t + {φ}_{3} ) ] + … \frac{{A}_{5} {A}_{ref}}{2} [ - sin ( 4 ω t + {φ}_{5} ) + sin ( 6 ω t + {φ}_{5} ) ] + … \qquad ( 5 )$$

while multiplication of expressions (2) and (3) provides

$$\begin{matrix}\frac{{A}_{1} {A}_{ref}}{2} [ sin φ + sin ( 2 ω t + φ ) ] + \frac{{A}_{3} {A}_{ref}}{2} [ sin ( 2 ω t + {φ}_{3} ) + sin ( 4 ω t + {φ}_{3} ) ] + … \frac{{A}_{5} {A}_{ref}}{2} [ sin ( 4 ω t + {φ}_{5} ) + sin ( 6 ω t + {φ}_{5} ) ] + … & \end{matrix} \qquad ( 6 )$$

The difference between (6) and (5) now provides
A₁A_{ref} sin φ+A₃A_{ref} sin(2ωt+φ₃)+A₅A_{ref} sin(4ωt+φ₅)+ (7)
With suitable filtering, 2^{nd} and higher harmonics in this signal can be removed. Thus, an expression is obtained providing a measure for the phase difference between the reference signal and the fundamental harmonic frequency component of the mains signal.

An expression providing a measure, according to the invention, for the amplitude of the fundamental harmonic frequency component of the mains signal can be determined in a manner similar to the above, by multiplying expressions (1) and (3), and multiplying expressions (2) and (4), adding the results of the multiplications and (if required), removing higher harmonics of the reference signal and/or the fundamental harmonic frequency of the mains signal with a suitable filtering.

Thus, the invention provides a method and system for feeding electrical energy into the mains wherein a high efficiency can be achieved as the feeding of energy into the mains is synchronized to the fundamental harmonic frequency of the mains signal, and thus substantially only on this frequency energy is fed into the mains. Further, energy control for controlling the amount of energy to be fed into the mains and/or a phase compensation for compensating for a reactance such as an inductance in long lines in or to the mains can be easily added. As the method according to the invention only requires simple and easy to perform steps, they can be easily implemented in for example a signal processor, such as a digital signal processor or any other processing or calculating unit. Alternatively, it is however also possible to perform these operations in suitable hardware, comprising e.g. delay circuits, multiplication circuits etc.

1. A method for feeding electrical energy into an alternating current electrical mains, the method comprising the steps of:
a) recording a mains signal for obtaining a measured mains signal;
b) generating a reference signal having a fundamental harmonic frequency which is within a tolerance band around a fundamental harmonic frequency of the mains signal;
c) deriving a delayed mains signal from the measured mains signal;
d) deriving a delayed reference signal from the reference signal;
e) multiplying the delayed mains signal with the reference signal for obtaining a first multiplied signal;
f) multiplying the mains signal with the delayed reference signal for obtaining a second multiplied signal;
g) determining a phase difference between a fundamental harmonic frequency of the mains signal and the fundamental harmonic frequency of the reference signal by determining a difference between the first and the second multiplied signals;
h) adjusting the fundamental harmonic frequency of the reference signal based on the phase difference;
i) synchronizing a converter for converting the energy into an alternating current electrical energy, to the adjusted fundamental harmonic frequency of the reference signal; and
j) feeding the alternating current electrical energy into the mains, in phase with the reference signal.

2. The method according to claim 1, further comprising the steps of:
k) multiplying the mains signal with the reference signal for obtaining a third multiplied signal;
l) multiplying the delayed mains signal with the delayed reference signal for obtaining a fourth multiplied signal;
m) determining an amplitude of the fundamental harmonic frequency component of the mains signal by determining a sum of the third and the fourth multiplied signals; and wherein step j) comprises the further step of:
j1) determining a magnitude of the electrical energy to be fed into the mains, based on the amplitude of the fundamental harmonic frequency component of the mains signal.

3. The method according to claim 1, characterized in that the delayed mains signal and the delayed reference signal are each delayed by a time period of substantially one quarter of a repetition time of the reference signal.

4. The method according to claim 1, characterized in that the method comprises the further step of, prior to step h):
averaging the phase difference over a repetition time of the reference signal.

5. The method according to claim 2, characterized in that the method comprises the further step of, prior to step j1):
averaging the amplitude over the repetition time of the reference signal.

6. The method according to claim 1, characterized in that the reference signal is a substantially sinusoidal signal.

7. The method according to claim 1, characterized by repeating at least steps a) to j).

8. A system for feeding electrical energy into an alternating current electrical mains, the system comprising:
an energy source for supplying the electrical energy to the system,
a converter for converting the electrical energy into an alternating current energy, and
a synchronization circuit for synchronizing the converter to a repetition frequency of the alternating current mains, characterized in that
the synchronization circuit comprises means for
a) recording a mains signal for obtaining a measured mains signal;
b) generating a reference signal having a fundamental harmonic frequency which is within a tolerance band around a fundamental harmonic frequency of the mains signal;
c) deriving a delayed mains signal from the measured mains signal;
d) deriving a delayed reference signal from the reference signal;
e) multiplying the delayed mains signal with the reference signal for obtaining a first multiplied signal;
f) multiplying the mains signal with the delayed reference signal for obtaining a second multiplied signal;
g) determining a phase difference between a fundamental harmonic frequency of the mains signal and the fundamental harmonic frequency the reference signal by determining a difference between the first and the second multiplied signals;
h) adjusting the fundamental harmonic frequency of the reference signal based on the phase difference;
i) synchronizing the converter to the adjusted fundamental harmonic frequency of the reference signal;
and in that the converter comprises means for feeding the electrical energy into the mains, in phase with the reference signal.

9. The system according to claim 8, characterized in that the synchronization circuit comprises a digital signal processor.

10. The system according to claim 8, characterized in that the energy source comprises at least one solar cell and in that the converter comprises an inverter.
